(19) United States
(12) Patent Application Publication
(10) Pub. No.: US 2005/0154962 A1
(43) Pub. Date: Jul. 14, 2005

(54) Method and system to spin up a hard disk prior to a hard disk data exchange request

(76) Inventors: Andrew S. Grover, Beaverton, OR (US); Brian A. Leete, Beaverton, OR (US)

Correspondence Address: John P. Ward;BLAKELY, SOKOLOFF, TAYLOR & ZAFMAN LLP, Seventh Floor, 12400 Wilshire Boulevard, Los Angeles, CA, 90025, US

(21) Appl. No.: 10/750,037

(22) Filed: Dec. 30, 2003

(51) Int. Cl. G11C 29/00

(52) U.S. Cl. 714/763

(57) ABSTRACT

Method and system to spin up a hard disk prior to a data exchange request. In one embodiment, the occurrence of a predetermined event is detected. In response, the hard disk is activated prior to a request to exchange data with the hard disk. In one embodiment, the predetermined event is a cacche of the hard disk reaching a predetermined level of dirty data, the predetermined level being less than completely full. In an alternative embodiment, the predetermined event includes detecting a presence of a computer user.

### NOTICE OF RELATED APPLICATIONS

This application is related to copending patent application titled METHOD AND SYSTEM TO ADJUST NON-VOLATILE CACHE ASSOCIATIVITY, patent application No. ______ filed Dec. 30, 2003 (Attorney Docket No. 42.P18166), copending patent application titled METHOD AND APPARATUS TO SAVE HISTORICAL HARD DISK PERFORMANCE DATA, patent application No. ______ filed Dec. 30, 2003 (Attorney Docket No. 42.P18167), and copending patent application titled METHOD AND SYSTEM TO CHANGE A POWER STATE OF A HARD DRIVE, patent application No. ______ filed Dec. 30, 2003 (Attorney Docket No. 42.P18169).

### FIELD OF INVENTION

The field of invention relates generally to data processing; and, more specifically, to a method and system for spinning up a hard disk prior to a request to exchange data.

### BACKGROUND

Today, run time power management on operating systems for hard disks, consists of at least two typical cases. One, if the hard disk doesn't receive requests in X minutes, the hard disk spins down. Two, if there is no mouse or keyboard activity for Y minutes the screen blanks. Typically when the system is idle, both these conditions become true. When the user returns and wiggles the mouse, the screen turns back on, but the drive remains off until the user performs an activity that requires hard disk activity. Then the user must wait while the disk spins up. The latency of a hard disk spinning up may be three to five seconds.

In addition, a hard disk may be provided with a cache for the hard disk, typically found in random access memory (RAM), to cache data which has been read from the hard disk. However, because the hard disk cache is located in the RAM, data which is to be written to the hard disk is unable to be cached in the cache of the hard disk, because if the computer system were to fail the data to be written to the hard disk would be lost due to the loss of power to the RAM.

### BRIEF DESCRIPTION OF THE DRAWINGS

FIG. 1 presents a flow diagram describing the processes of spinning up a hard disk prior to a data exchange request according to one embodiment.

FIG. 2 presents a diagram of a system to spin up a hard disk prior to a data exchange request according to one embodiment.

FIG. 3 presents a flow diagram describing the process of spinning up the hard disk prior to a data exchange request according to an alternative embodiment.

FIG. 4 presents a flow diagram describing the process of spinning up the hard disk prior to a data exchange request according to yet another alternative embodiment.

FIG. 5 presents a diagram of a non-volatile memory unit used as a cache for the hard disk of a computer system according to one embodiment.

### DETAILED DESCRIPTION

A method and system for spinning up a hard disk prior to a request to exchange data are described. In one embodiment, the occurrence of a predetermined event is detected. In response, the hard disk is activated prior to a request to exchange data with the hard disk. In one embodiment, the predetermined event is a cache of the hard disk reaching a predetermined level of dirty data, the predetermined level being less than completely full. In an alternative embodiment, the predetermined event includes detecting a presence of a computer user.

In the following description, numerous specific details are set forth. However, it is understood that embodiments may be practiced without these specific details. In other instances, well-known circuits, structures and techniques have not been shown in detail in order not to obscure the understanding of this description.

Reference throughout this specification to “one embodiment” or “an embodiment” indicate that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. In addition, as described herein, a trusted platform, components, units, or subunits thereof, are interchangeably referenced as a protected or secured.

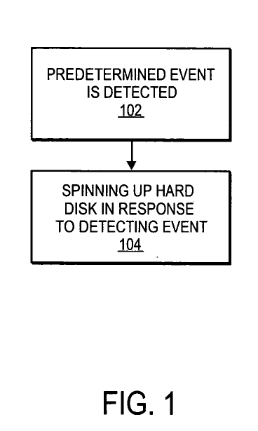

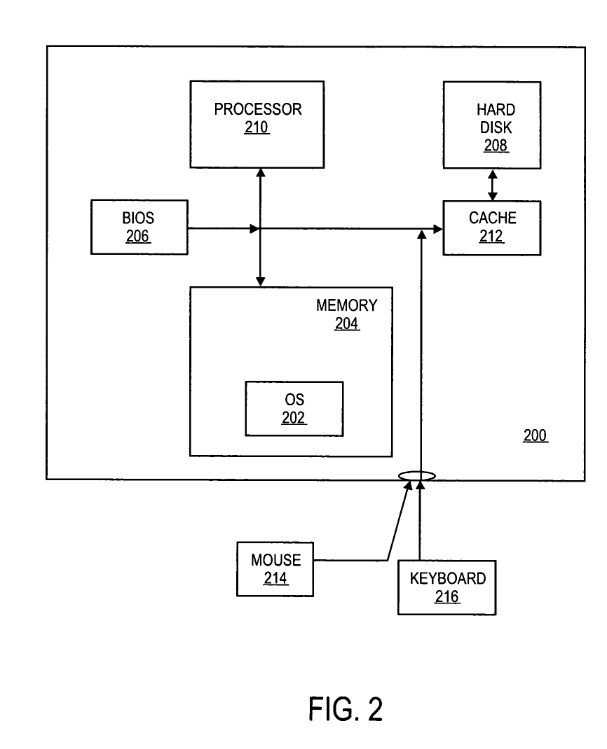

FIG. 1 presents a flow diagram describing the processes of spinning up a hard disk prior to a data exchange request according to one embodiment. The flow diagram is described with reference to the computer system 200 illustrated in the diagram of FIG. 2.

In process 102, the occurrence of a predetermined event is detected within the computer system 200. In one embodiment, the occurrence of the predetermined event is detected by an operating system 202 within the system, shown stored in memory 204 of the system. Alternatively, a driver of a component within the system, such as the driver 201 of the hard disk (HD), may detect the occurrence of the predetermined event. In other alternative embodiments, alternative units may be used to detect the occurrence of the predetermined event, such as the Basic Input Output System (BIOS) 206.

In process 104, in response to detecting the predetermined event, the hard disk 208 of the computer system is activated from a deactive state. Activating the hard disk is also referenced herein as spinning up the hard disk, when the hard disk had previously been spun down. In one embodiment, the hard disk may have been spun down in response to having not received a request within a predetermined period of time, to write or read data to or from the drive (herein referenced as exchanging data with the hard disk). In one embodiment, the process of spinning up the hard disk occurs before there is a need or request to exchange to or from the hard disk. The hard disk, as referenced herein, includes a primary storage medium of the system.

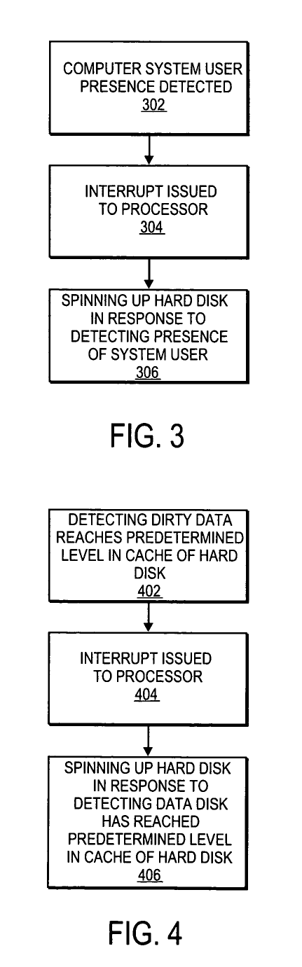

FIG. 3 presents a flow diagram describing the process of spinning up the hard disk prior to a data exchange request according to an alternative embodiment. Again, the flow diagram is described with reference to the computer system 200 illustrated in the diagram of FIG. 2.

In process 302, the presence of a computer user is detected by the computer system 200. In one embodiment, the presence of the computer user includes detecting movement of input device, such as a mouse 214, a trackball, or other input device. In addition, the presence of the computer user may be detected by detecting a key on the keyboard 216 being activated or pressed down. In yet another alternative embodiment, the presence of the computer user may be detected by a camera (not shown) of the computer system 200. In alternative embodiments, other types of techniques may be used to detect the presence of a computer user.

In one embodiment, in response to detecting a presence of computer user, in process 304 an interrupt is transmitted to the processor 210. In response to the interrupt identifying the presence of a computer user, in process 306 the processor signals the operating system (or an alternative unit within the system 202, such as the driver 201 of the hard disk) to spin up or active the hard disk 208, prior to an actual request or need to exchange data with the hard disk 208.

FIG. 4 presents a flow diagram describing the process of spinning up the hard disk prior to a data exchange request according to yet another alternative embodiment. Again, the flow diagram is described with reference to the computer system 200 illustrated in the diagram of FIG. 2.

In process 402, dirty data in a cache 212 to the hard disk 208 reaches a predetermined level. In one embodiment, the predetermined level is to be reached before hard disk cache 212 is full of dirty data. Dirty data, as referenced herein includes data that is to be written to the hard disk, otherwise referenced as updated data.

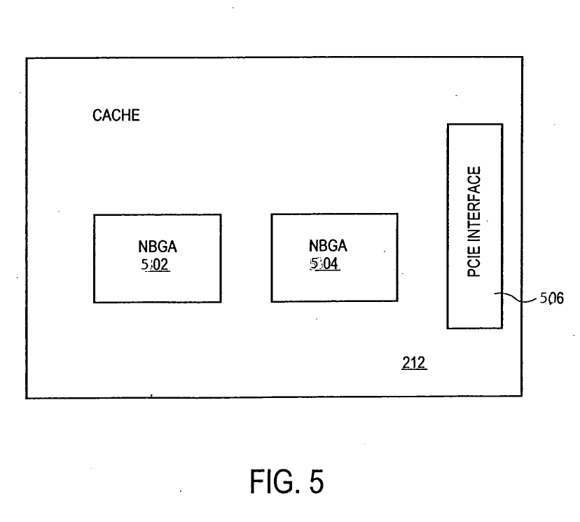

In one embodiment, the cache 212 to the hard disk 208 is a non volatile memory unit. As a result, if the system were to lose power before the dirty data of the cache 212 has been written to the hard disk 208, the dirty data would still remain stored on the cache 212, and could be accessed when power is restored. In one embodiment, In one embodiment, as illustrated in FIG. 5, the cache 212 of the hard disk 208 is a thin film electronics memory made of Ferroelectric polymer with multiple layers stacked on top of standard complimentary metal oxide semiconductor (CMOS). In one embodiment, the cache 212 of the hard disk 208 has a 512 megabyte (mb) capacity. In one embodiment, the cache comprises two 256 mb microBall Grid Arrays (BGA) 502, 504. In one embodiment, the cache 212 includes a form factor of a Mini Peripheral Component Interconnect Express (PCIE) card, and also includes PCIE interface 506. In alternative embodiments, the cache 212 may be made of alternative materials, consist of an alternative capacity, an alternative form factor, and/or and alternative interface.

In response to detecting dirty data in the cache 212 to the hard disk 208 has reached a predetermined level before the cache is full of dirty data, in process 404 an interrupt is transmitted to the processor 210. In response to the interrupt notifying that the dirty data in the cache 212 to the hard disk 208 has reached the predetermined level, in process 406 the processor signals the operating system or the driver 201 of the HD 208 to spin up or active the hard disk 208, prior to an actual request or need to exchange data with the hard disk 208. In one embodiment, a cache manager would keep track of the level of dirty data in the cache 212, relative to the predetermined level. In response, the cache manager would then cause an interrupt or submit a request to have the HD 208 spin up. The cache manager could be part of the HD driver 201, or separate working in concert with the HD driver 201, or working in a layered fashion.

The processes described above can be stored in the memory of a computer system as a set of computer-readable instructions to be executed. In addition, the instructions to perform the processes described above could alternatively be stored on other forms of machine-readable media, including magnetic and optical disks. For example, the processes described could be stored on machine-readable media, such as magnetic disks or optical disks, which are accessible via a hard disk (or computer-readable medium drive). Further, the instructions can be downloaded into a computing device over a data network in a form of compiled and linked version.

Alternatively, the logic to perform the processes as discussed above could be implemented in additional computer and/or machine readable media, such as discrete hardware components as large-scale integrated circuits (LSI's), application-specific integrated circuits (ASIC's), firmware such as electrically erasable programmable read-only memory (EEPROM's); and electrical, optical, acoustical and other forms of propagated signals (e.g., carrier waves, infrared signals, digital signals, etc.); etc.

In the foregoing specification, the invention has been described with reference to specific exemplary embodiments thereof. It will, however, be evident that various modifications and changes may be made thereto without departing from the broader spirit and scope of the invention as set forth in the appended claims. For example, the non-volatile memory unit, as described herein, may be used as a cache for other components within a system, other than the HD. The specification and drawings are, accordingly, to be regarded in an illustrative rather than a restrictive sense.

1. A method comprising:
a system detecting an occurrence of a predetermined event;
in response to detecting the event, spinning up a hard disk of the system prior to a request to exchange data with the hard disk.

2. The method of claim 1, wherein the predetermined event is a cache of the hard disk reaching a predetermined level of dirty data, the predetermined level is to be reached before the cache of the hard disk is full of dirty data.

3. The method of claim 2, wherein the cache of the hard disk consists of nonvolatile memory.

4. The method of claim 1, wherein the predetermined event includes detecting a presence of a system user.

5. The method of claim 1, wherein the predetermined event includes detecting one of movement and activation of one of an input device and a pointing device.

6. The method of claim 1, wherein the predetermined event includes detecting movement of a mouse or activation of a key on a keyboard.

7. A machine readable medium having stored thereon a set of instructions which when executed cause a system to perform a method comprising of:
the system detecting an occurrence of a predetermined event;
in response to detecting the event, spinning up a hard disk of the system prior to a request to exchange data with the hard disk.

8. The machine readable medium of claim 7, wherein the predetermined event is a cache of the hard disk reaching a predetermined level of dirty data, the predetermined level is to be reached before cache of the hard disk is full of dirty data.

9. The machine readable medium of claim 8, wherein the cache of the hard disk consists of nonvolatile memory.

10. The machine readable medium of claim 7, wherein the predetermined event includes detecting a presence of a system user.

11. The machine readable medium of claim 7, wherein the predetermined event includes detecting one of movement and activation of one of an input device and a pointing device.

12. A system comprising:
a processor;
a non-volatile cache coupled to the processor; and
a machine readable medium having stored thereon a set of instructions which when executed cause the system to pe
